(19) United States
(12) Patent Application Publication
(10) Pub. No.: US 2022/0224082 A1
(43) Pub. Date: Jul. 14, 2022

(54) VERTICAL CAVITY SURFACE EMITTING LASER DEVICE AND MANUFACTURING METHOD THEREOF

(71) Applicant: ABOCOM SYSTEMS, INC., Miaoli County (TW)

(72) Inventors: CHIH-YUAN LIN, MIAOLI COUNTY (TW); CHENG-YI OU, MIAOLI COUNTY (TW); TE-LIEH PAN, MIAOLI COUNTY (TW); CHENG-HSIAO CHI, MIAOLI COUNTY (TW)

(21) Appl. No.: 17/563,065

(22) Filed: Dec. 28, 2021

(30) Foreign Application Priority Data
Jan. 8, 2021 (TW) 110100817

(51) Int. Cl. H01S 5/183; H01S 5/30

(52) U.S. Cl. CPC H01S 5/18377; H01S 5/3095; H01S 5/18394

(57) ABSTRACT

A vertical cavity surface emitting laser (VCSEL) device includes a substrate, a first mirror layer, an active layer, an oxide layer, a second mirror layer, a tunnel junction layer and a third mirror layer sequentially stacked with one another. The first mirror layer and the third mirror layer are N-type distributed Bragg reflectors (N-DBR), and the second mirror layer is P-type distributed Bragg reflector (P-DBR). The tunnel junction layer is provided for the VCSEL device to convert a part of the P-DBR into N-DBR to reduce the series resistance of the VCSEL device, and the tunnel junction layer is not used as current-limiting apertures. This disclosure further discloses a VCSEL device manufacturing method with the in-situ and one-time epitaxy features to avoid the risk of process variation caused by moving the device into and out from an epitaxial cavity.

### CROSS-REFERENCE TO RELATED APPLICATIONS

This non-provisional application claims priority under 35 U.S.C. § 119(a) on Patent Application No(s). 110100817 filed in Taiwan, R.O.C. on Jan. 8, 2021, the entire contents of which are hereby incorporated by reference.

### BACKGROUND

### Technical Field

The present disclosure relates to a vertical cavity surface emitting laser (VCSEL) device and its manufacturing method, and more particularly to the VCSEL device and its manufacturing method using a P-type distributed Bragg reflector (DBR) with less stacked layers to achieve low series resistance.

### Description of Related Art

Semiconductor light emitting device can be divided into Light-Emitting Diode (LED) device and Laser Diode (LD) device. The LED device is a divergent light source with weak luminous energy and too-large beam angle, so that its functionality is insufficient and can only be applied for general lighting or used in 2D sensing systems. On the other hand, the laser beam generated by the LD device has large beam angle and better shape than those of the LED device and the advantages of low power consumption, high efficiency and high speed, so that the LD device is applicable for the fields of 3D sensing and optical communication. As to the structural aspect, the structure of the LD device is more complicated, the material requirement is higher, and the design is more difficult, and the epitaxy technology with a high level of difficulty is required for the mass production of the LD device. Although both the LD device and the LED device are light emitting devices, their uses, effects, structures and technical fields are different.

As the name suggests, the vertical cavity surface emitting laser (VCSEL) device emits a laser beam vertically from the surface of a grain surface, and the LD device is one of the VCSEL devices. For example, Gallium Arsenide (GaAs) is used as a substrate of the VCSEL device, a first mirror layer is formed at the top of the substrate, an active layer is formed at the top of the first mirror layer, an oxide layer is formed at the top of the active layer, and a second mirror layer is formed at the top of the oxide layer. As an example, wet oxidation is used to manufacture the VCSEL device, the substrate is an N-type (n+GaAs or N−GaAs) substrate, the first mirror layer is an N-type distributed Bragg reflector (N-DBR), and the second mirror layer is a P-type distributed Bragg reflector (P-DBR). The VCSEL device uses the second mirror layer and the first mirror layer disposed at the top and bottom of the active layer respectively as reflective mirror surfaces to generate a laser beam emitted from a resonant cavity.

For example, the N-DBR is generally formed by repeatedly stacking a stacked pair composed of a lower layer Al_{0.12}Ga_{0.88}As and an upper layer Al_{0.9}Ga_{0.1}As, wherein the N-DBR can be obtained by doping silicon with an undoped DBR, and the N-DBR has approximately 35 silicon-doped stacked pairs. The P-DBR is also formed by repeatedly stacking a stacked pair composed of a lower layer Al_{0.12}Ga_{0.88}As and an upper layer Al_{0.9}Ga_{0.1}As, and the P-DBR can be obtained by doping carbon with an undoped DBR, and the P-DBR has approximately 25 carbon-doped stacked pairs. The N-DBR and the P-DBR adopt a total of approximately 60 stacked pairs (or approximately 120 layers) to achieve high reflectivity of approximately 99.9% for the N-DBR and approximately 99.0% for the P-DBR. However, the large quantity of layers (up to 120 layers) also leads to high series resistance.

In one of the methods, the high series resistance is overcome by performing a high-concentration silicon and carbon doping for the N-DBR and the P-DBR respectively, but actually the carbon doping concentration of P-DBR (which is a P-type semiconductor) has an upper limit of approximately 0.30×10¹⁹˜1.0×10¹⁹ atoms/cm³, so that the resistance value of the P-DBR cannot be lower than the required resistance value. Even though the carbon doping concentration of the P-DBR can be 1.0×10¹⁹ atoms/cm³ or above, it will be difficult to control the reproducibility and uniformity of the P-DBR with the same thickness during the epitaxial process, and the traditional VCSEL device has an issue of unable to overcome the high series resistance of the P-DBR effectively.

### SUMMARY

Therefore, it is a primary objective of the present disclosure to overcome the problems of the prior art by providing a VCSEL device and its manufacturing method in accordance with the present disclosure.

To achieve the foregoing and other objectives, the present disclosure discloses a VCSEL device and its manufacturing method based on the N-DBR can achieve a doping concentration higher than that of the P-DBR to effectively reduce the series resistance, and the effective mass of electron is smaller than that of the electron hole, and the resistance of the N-DBR will not be affected by the oxide apertures disposed at the center of the oxide layer, so that the resistance of the P-DBR is much greater than that of the N-DBR. In this way, a majority of the series resistance of the VCSEL device comes from the P-DBR, so that the present disclosure can reduce the series resistance of the VCSEL device by converting a part of the P-DBR into N-DBR.

This disclosure discloses a VCSEL device and its manufacturing method, and the VCSEL device includes: a substrate; a first mirror layer, disposed at the top of the substrate, and the first mirror layer is a first N-type distributed Bragg reflector; an active layer, disposed at the top of the first mirror layer; an oxide layer, disposed at the top of the active layer; a second mirror layer, disposed at the top of the oxide layer, and the second mirror layer is a P-type distributed Bragg reflector; a tunnel junction layer, disposed at the top of the second mirror layer; and a third mirror layer, disposed at the top of the tunnel junction layer and the third mirror layer is a second N-type distributed Bragg reflector, wherein each of the second mirror layer and the third mirror layer includes a plurality of stacked pairs, and each stacked pair includes a first layer and a second layer; the tunnel junction layer includes a heavily-doped N-type layer and a heavily-doped P-type layer, and an N-type filling layer is disposed between the heavily-doped N-type layer and the third mirror layer, and a P-type filling layer is disposed between the heavily-doped P-type layer and the second mirror layer, and the sum of the thickness of the heavily-doped N-type layer and the thickness of the N-type filling layer is equal to the thickness of the second layer, and the sum of the heavily-doped P-type layer and the thickness of the P-type filling layer is equal to the thickness of the first layer; or the sum of the thickness of the heavily-doped N-type layer, the thickness of the N-type filling layer, the thickness of the heavily-doped P-type layer and the thickness of the P-type filling layer is equal to the thickness of the first layer or the thickness of the second layer.

In another embodiment, the tunnel junction layer has an area equal to the area of the second mirror layer and/or the area of the third mirror layer.

In another embodiment, the oxide layer includes an oxide aperture disposed at a central area and an oxide area disposed around the oxide aperture, and the oxide aperture has an area smaller than the area of the tunnel junction layer.

In another embodiment, the tunnel junction layer has an area equal to the area of the second mirror layer and/or the area of the third mirror layer; and he oxide layer includes an oxide aperture disposed at a central area and an oxide area disposed around the oxide aperture, and the oxide aperture has an area smaller than the area of the tunnel junction layer.

The present disclosure further discloses a vertical cavity surface emitting laser (VCSEL) device manufacturing method using an in-situ and one-time epitaxy to avoid the risk of process variation. The VCSEL device manufacturing method includes the following epitaxy steps: providing a substrate in a cavity; forming a first mirror layer in-situ at the cavity on the substrate, wherein the first mirror layer is a first N-type distributed Bragg reflector; forming an active layer and an oxide layer sequentially in-situ at a cavity on the first mirror layer; forming a second mirror layer in-situ at a cavity on the oxide layer, wherein the second mirror layer is a P-type distributed Bragg reflector; forming a tunnel junction layer in-situ at a cavity on the second mirror layer; forming a third mirror layer in-situ at a cavity on the tunnel junction layer, wherein the third mirror layer is a second N-type distributed Bragg reflector, and the tunnel junction layer has an area equal to the area of the second mirror layer and/or the area of the third mirror layer; the oxide layer includes an oxide aperture disposed at a central area and an oxide area disposed around the oxide aperture, and the oxide aperture has an area smaller than the area of the tunnel junction layer; each of the second mirror layer and the third mirror layer includes a plurality of stacked pairs, and each stacked pair includes a first layer and a second layer; the tunnel junction layer includes a heavily-doped N-type layer and a heavily-doped P-type layer, and an N-type filling layer is disposed between the heavily-doped N-type layer and the third mirror layer, and a P-type filling layer is disposed between the heavily-doped P-type layer and the second mirror layer, and the sum of the thickness of the heavily-doped N-type layer and the thickness of the N-type filling layer is equal to the thickness of the second layer, and the sum of the thickness of the heavily-doped P-type layer and the thickness of the P-type filling layer is equal to the thickness of the first layer, or the sum of the thickness of the heavily-doped N-type layer, the thickness of the N-type filling layer, the thickness of the heavily-doped P-type layer and the thickness of the P-type filling layer is equal to the thickness of the first layer or the thickness of the second layer.

### BRIEF DESCRIPTION OF THE DRAWINGS

FIG. 1 is a cross-sectional view showing the structure of a VCSEL device in accordance with this disclosure;

FIG. 2 is a cross-sectional view showing the structure of a VCSEL device having a stacked pair in accordance with this disclosure;

FIG. 3 is a cross-sectional view showing the structure of a tunnel junction layer and a filling layer in accordance with this disclosure;

FIG. 4 is a flow chart showing the epitaxy steps of a VCSEL device manufacturing method in accordance with this disclosure; and

FIG. 5 shows an electric field amplitude versus distance graph to compare a VCSEL device of the present disclosure with a traditional VCSEL device.

### DESCRIPTION OF THE EMBODIMENTS

This disclosure will now be described in more detail with reference to the accompanying drawings that show various embodiments of the invention.

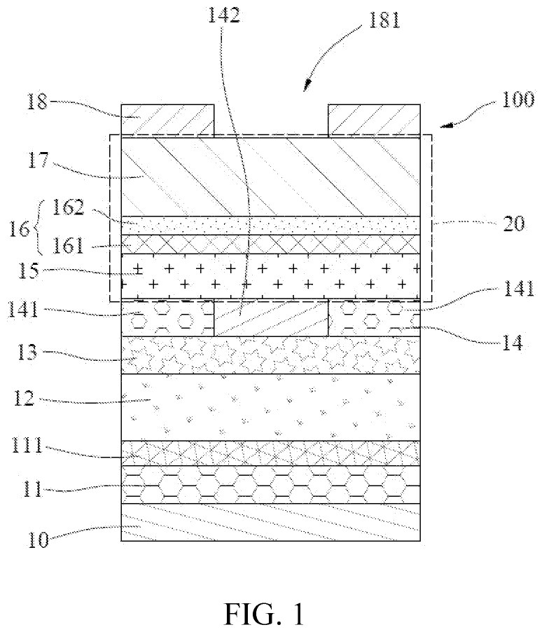

With reference to FIG. 1 for a vertical cavity surface emitting laser (VCSEL) device 100 of the present disclosure, the VCSEL device includes a first electrode 10; a substrate 11, contacted with the first electrode 10, and installable at the top or bottom of the first electrode 10; a first mirror layer 12, disposed at the top of the substrate 11, wherein the first mirror layer 12 can be a first N-type distributed Bragg reflector (first N-DBR), and the first mirror layer 12 can be contacted with the upper surface of the substrate 11; an active layer 13, disposed at the top of the first mirror layer 12,and contactable with the upper surface of the first mirror layer 12; an oxide layer 14, disposed at the top of the oxide layer 14; a second mirror layer 15, disposed at the top of the oxide layer 14, wherein the second mirror layer 15 can be a P-type distributed Bragg reflector (P-DBR) contactable with the upper surface of the oxide layer 14; a tunnel junction (TJ) layer 16, disposed at the top of the second mirror layer 15 and contactable with the upper surface of the second mirror layer 15; a third mirror layer 17, disposed at the top of the tunnel junction layer 16, wherein the third mirror layer 17 can be a second N-type distributed Bragg reflector (second N-DBR) and contactable with the upper surface of the tunnel junction layer 16; and a second electrode 18, disposed at the top of and contactable with the third mirror layer 17. In other words, the VCSEL device 100 includes: the substrate 11, the first mirror layer 12, the active layer 13, the oxide layer 14, the second mirror layer 15, the tunnel junction layer 16 and the third mirror layer 17 sequentially arranged from bottom to top.

The first electrode 10 and the second electrode 18 can be made of gold, silver, copper, iron, cobalt, nickel, titanium or their analogues or alloys, wherein the alloy can be zinc alloy or germanium alloy, and the first electrode 10 and the second electrode 18 can be made of the same material or different materials. Basically, the first electrode 10 and the second electrode 18 can be both N-type (ohmic) electrodes or can be both P-type (ohmic) electrodes. For example, the first electrode 10 is an N-type electrode and the second electrode 18 is also N-type electrode. The second electrode 18 is in a ring shape, with its central area acting as a light exit aperture 181, and the VCSEL device 100 can emit a laser beam through the light exit aperture 181.

The substrate 11 can be made of a common monocrystalline semiconductor material such as the gallium arsenide (GaAs), gallium nitride (GaN), aluminium gallium arsenide (AlGaAs) or gallium phosphide (GaP) substrate. Preferably, the substrate 11 is a GaAs substrate. Preferably, the substrate 11 is a GaAs substrate. The substrate 11 includes a buffer layer 111 made of the same material, and the buffer layer 111 is an N-type semiconductor layer and can be a part of the substrate 11. The substrate 11 must have a smooth crystal surface provided for the subsequent epitaxy growth process of forming the first mirror layer 12 on the upper surface of the buffer layer 111. In other words, the first mirror layer 12 is grown on the upper surface of the substrate 11.

Each of the first mirror layer 12, second mirror layer 14 and third mirror layer 17 is a multilayer structure, in which each adjacent layer is made of alternately stacked semiconductor materials with different refractive indexes. The first mirror layer 12 (or first N-DBR) is an N-type semiconductor layer such as a doped silicon (Si) and/or tellurium (Te) AlGaAs layer. The second mirror layer 14 (P-DBR) is a P-type semiconductor layer such as a doped carbon (C) and/or zinc (Zn) AlGaAs layer. Each of the first mirror layer 12 and the second mirror layer 14 is an AlGaAs multilayer structure with different aluminium mole percentages to change the refractive index. The third mirror layer 17 (or second N-DBR) is also an N-type semiconductor layer such as a doped silicon (Si) and/or tellurium (Te) AlGaAs layer. The first mirror layer 12 and the third mirror layer 17 can be the same N-type semiconductor layer or different N-type semiconductor layers. Each of the first mirror layer 12 and the third mirror layer 17 has a reflectivity greater than 99.9%, and the overall reflectivity of the combined first mirror layer 12, tunnel junction layer 13 and second mirror layer 14 is also greater than 99.9%.

The tunnel junction layer 16 can be a multilayer structure including a heavily-doped P-type layer 161 and a heavily-doped N-type layer 162. In the tunnel junction layer 16, the heavily-doped P-type layer 161 is disposed adjacent to the second mirror layer 15, and the heavily-doped N-type layer 162 is disposed adjacent to the third mirror layer 17. The tunnel junction layer 16 is made of a material such as GaAs, AlGaAs, InGaP, AlInP, AlGaInP or InGaAsP. For example, the heavily-doped N-type layer 162 is a doped silicon (Si) and/or tellurium (Te) AlGaAs layer or a Group III phosphide semiconductor layer such as an indium gallium phosphate (InGaP) layer; and the heavily-doped P-type layer 161 is a doped carbon (C) AlGaAs layer or a Group III phosphide semiconductor layer (such as an InGaP layer).

The active layer 13 can include one or more quantum well layers with spectral gap wavelength, and each quantum well layer emits laser beams under an operating wavelength. For example, the active layer 13 can include an AlGaAs layer, a GaAs layer, a gallium arsenic phosphide (GaAsP) layer or an indium gallium arsenide (InGaAs) layer. The active layer 13 can also include quantum holes or other device structures with an appropriate light emitting property such as quantum dots or similar device structures. The quantum well layers, quantum holes or quantum dots are disposed in the active layer 13 and separated to generate the required laser beams.

The oxide layer 14 can be an optically and electrically limited oxide layer formed by oxidizing one or more epitaxial layers. For example, the oxide layer 14 can be an oxide area 141 of aluminium oxide (Al₂O₃) formed by a lateral oxidation of the epitaxial layer (such as an AlGaAs layer) and an oxide aperture 142 including a metal (such as unoxidized aluminium) and disposed at a central area. Therefore, the oxide area 141 is an insulated area disposed around the conductive oxide aperture 142, and the oxide aperture 142 is passed through the oxide area 141 to form a conductive path with a limited area, and electricity and light (laser beam) are passed from the oxide aperture 142, and the oxide aperture 142 is a current-limiting aperture. The smaller the oxide aperture 142, the larger the resistance value. The oxide aperture 142 can be formed at the bottom of the light exit aperture 181, and the oxide aperture 142 is slightly smaller than the light exit aperture 181.

It is noteworthy that the tunnel junction layer 16 is disposed between the second mirror layer 15 and the third mirror layer 17, so that the second N-DBR of the third mirror layer 17, the tunnel junction layer 16 and the P-DBR of the second mirror layer 15 can be formed with the same or substantially similar valence band, and the combination of the third mirror layer 17, the tunnel junction layer 16 and the second mirror layer 15 can be formed into a P-type distributed Bragg reflector structure 20. In other words, the tunnel junction layer 16 is allowed to switch from the N-type semiconductor layer to the P-type semiconductor layer. For example, the tunnel junction layer 16 is switched from the P-DBR of the second mirror layer 15 to the second N-DBR of the third mirror layer 17. Therefore, the dimensions (including area and shape) of the tunnel junction layer 16 can be the same as those of the first mirror layer r 15 and/or the third mirror layer 17.

In addition, the tunnel junction layer 16 can be formed at the bottom of the oxide aperture 142, and the oxide aperture 142 has an area smaller than the tunnel junction layer 16, so that the VCSEL device 100 of the present disclosure uses the oxide aperture 142 with a smaller area as an electrically and optically limited channel, and the tunnel junction layer 16 with a larger area is not used as the electrically and optically limited channel. In other words, the tunnel junction layer 16 is not used for the effect of the current-limiting aperture. Further, the VCSEL device 100 of the present disclosure has the oxide aperture 142 and the tunnel junction layer 16 at the same time, and the effects and purposes of the oxide aperture 142 and the tunnel junction layer 16 are different. The oxide aperture 142 is a current-limiting aperture and the tunnel junction layer 16 is used to switch the P-DBR of the second mirror layer 15 to the second N-DBR of the third mirror layer 17.

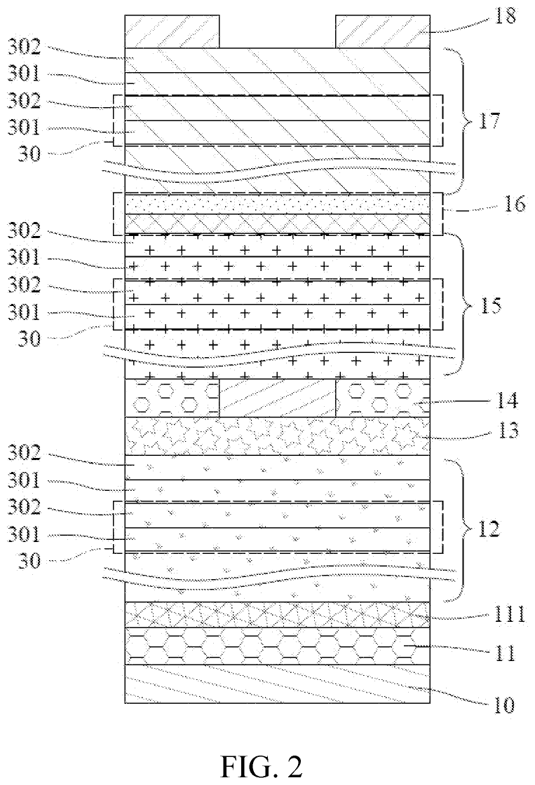

As described above, each of the first mirror layer 12, the second mirror layer 15 and the third mirror layer 17 is a multilayer structure with each adjacent layer made of alternately stacked semiconductor materials of different refractive indexes. In FIG. 2, each of the first mirror layer 12, the second mirror layer 15 and the third mirror layer 17 includes a plurality of stacked pairs 30. Each stacked pair 30 includes a first layer 301 and a second layer 302. The first layer 301 and the second layer 302 of the stacked pair 30 are formed by different materials of different concentrations, and the first layer 301 includes aluminium gallium arsenide (Al_{0.12}Ga_{0.88}As) having an aluminium concentration of 12% and a refractive index of 3.55; the second layer 302 includes aluminium gallium arsenide (Al_{0.9}Ga_{0.1}As) having an aluminium concentration of 90% and a refractive index of 2.93. In the calculation of thickness, each adjacent layer (including the first layer 301 and the second layer 302) has a thickness approximately equal to a quarter of the wavelength multiplied by the refractive index of each layer. The aforementioned wavelength refers to the wavelength (such as 850 nm) of the laser beam emitted by the VCSEL device. In an embodiment, the second mirror layer 15 has W stacked pairs 30, and the third mirror layer 17 has Z stacked pairs 30, and the sum of W and Z is approximately equal to 35, and Z is preferably an integer between 1 and 10 such as Z=1, 3, 5 or 10. Please refer to Table 1 below.

TABLE 1

| | | | | | | Dopant | |
|---|---|---|---|---|---|---|---|
| | | | | Thick- | | Content | No. of |
| DBR | Consti- | | X | ness | Do- | (atoms/ | Stacked |
| Type | tuent | Material | value | (nm) | pant | cm³) | Pairs |
| Third | Second | AlₓGa₁₋ | 0.9 | 72 | Si | Greater | W |
| mirror | layer | ₓAs | | | | than | |
| layer | | | | | | 3.0 × 10¹⁸ | |
| (second | First | AlₓGa₁₋ | 0.12 | 60 | Si | Greater | |
| N- | layer | ₓAs | | | | than | |
| DBR) | | | | | | 3.0 × 10¹⁸ | |
| Second | Second | AlₓGa₁₋ | 0.9 | 72 | C | 3.0 × 10¹⁸ | Z |
| mirror | layer | ₓAs | | | | | |
| layer | | | | | | | |
| (P- | First | AlₓGa₁₋ | 0.12 | 60 | C | 3.0 × 10¹⁸ | |
| DBR) | layer | ₓAs | | | | | |

Wherein, W+Z=35, and Z is an integer between 1 and 10.

Since the resistance of the P-DBR is much greater than the resistance of the N-DBR, most of the series resistance of the VCSEL device comes from the P-DBR, and the first mirror layer 12 and the third mirror layer 17 of the VCSEL device 100 of the present disclosure are N-DBRs, and only the second mirror layer 15 is a P-DBR. Compared with the traditional VCSEL device that requires 25 stacked pairs of the P-DBR the VCSEL device 100 of the present disclosure only has at most 10 stacked pair 30 of the P-DBR. Obviously, the VCSEL device 100 of the present disclosure can reduce the series resistance of the VCSEL device.

Based on the description above, the three-layer combination of the second mirror layer 15, the tunnel junction layer 16 and the third mirror layer 17 constitutes the P-type distributed Bragg reflector structure 20, so that the thickness of the heavily-doped P-type layer 161 and the thickness of the heavily-doped N-type layer 162 can be equal to the thickness of the first layer 301 (such as 60 nm as shown in Table 1) and the thickness of the second layer 302 (such as 72 nm as shown in Table 1) to comply with the design of reflectivity for the each stacked layer of the DBR (the P-type distributed Bragg reflector structure 20). Embodiments of various tunnel junction layers 16 will be described below.

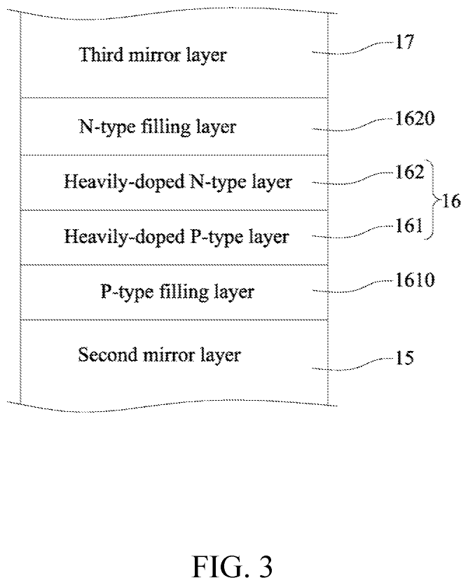

Basically, in order to achieve the tunnelling function, the thickness of the heavily doped N-type layer 161 of the tunnel junction layer 16 and the thickness of the heavily-doped N-type layer 162 of the tunnel junction layer 16 must be at least 10 nm (preferably 10 nm˜15 nm), and its doping concentration must be greater than 1.0×10²⁰ atoms/cm³ (preferably greater than 3.0×10²⁰ atoms/cm³). Therefore, based on the configuration of the heavily doped N-type layer 161 and the heavily-doped N-type layer 162 with a minimum thickness, another embodiment as shown in FIG. 3 is implemented, wherein a P-type filling layer 1610 is disposed between the heavily-doped P-type layer 161 and the second mirror layer 15, and an N-type filling layer 1620 is disposed between the heavily-doped N-type layer 162 and the third mirror layer 17. The sum of the thickness of the heavily-doped P-type layer 161 and the thickness of the P-type filling layer 1610 is equal to the thickness of the first layer 301, and the sum of the thickness of the heavily-doped N-type layer 162 and the thickness of the N-type filling layer 1620 is equal to the thickness of the second layer 302, thereby complying with the design of reflectivity of each stacked layer of the DBR (the P-type distributed Bragg reflector structure 20).

In another embodiment, the tunnel junction layer 16, the P-type filling layer 1610 and the N-type filling layer 1620 are AlGaAs layers, the VCSEL device 100 is sequentially and adjacently stacked with the second mirror layer 15, the P-type filling layer 1610, the heavily-doped P-type layer 161, the heavily-doped N-type layer 162, the N-type filling layer 1620 and the third mirror layer 17. Please refer to Table 2 below.

TABLE 2

| | | | | | | Dopant | |
|---|---|---|---|---|---|---|---|
| | | | | Thick- | | Content | No. of |
| | Consti- | | X | ness | Do- | (atoms/ | Stacked |
| Type | tuent | Material | value | (nm) | pant | cm³) | Pairs |
| Third | Second | AlₓGa₁₋ | 0.9 | 72 | Si | Greater | W |
| mirror | layer | ₓAs | | | | than | |
| layer | | | | | | 3.0 × 10¹⁸ | |
| (second | First | AlₓGa₁₋ | 0.12 | 60 | Si | Greater | |
| N- | layer | ₓAs | | | | than | |
| DBR) | | | | | | 3.0 × 10¹⁸ | |
| Filling | N-type | AlₓGa₁₋ | 0.12 | 57 | Si | Greater | — |
| layer | filling | ₓAs | | | | than | |
| | layer | | | | | 3.0 × 10¹⁸ | |
| Tunnel | Heavily- | AlₓGa₁₋ | 0.12 | 15 | Te | Greater | |
| xAs | doped | ₓAs | | | | than | — |
| junction | N-type | | | | | 3.0 × 10²⁰ | |
| layer | layer | | | | | | |
| (TJ) | Heavily- | AlₓGa₁₋ | 0.9 | 15 | C | Greater | — |
| | doped | ₓAs | | | | than | |
| | P-type | | | | | 3.0 × 10²⁰ | |
| | layer | | | | | | |
| Filling | P-type | AlₓGa₁₋ | 0.9 | 45 | C | 3.0 × 10¹⁸ | — |
| layer | filling | ₓAs | | | | | |
| | layer | | | | | | |
| Second | Second | AlₓGa₁₋ | 0.9 | 72 | C | About | |
| mirror | layer | ₓAs | | | | 3.0 × 10¹⁸ | Z |
| layer | First | AlₓGa₁₋ | 0.12 | 60 | C | | |
| (P- | layer | ₓAs | | | | | |
| DBR) | | | | | | | |

Wherein, the sum (60 nm) of the thickness of the heavily-doped P-type layer 161 (15 nm) and the thickness of the P-type filling layer 1610 (45 nm) is equal to the thickness of the first layer 301 (60 nm), and the sum (72 nm) of the thickness of the heavily-doped N-type layer 162 (15 nm) and the thickness of the N-type filling layer 1620 (57 nm) is equal to the thickness of the second layer 302 (72 nm). Wherein, W+Z=35, and Z is an integer between 1 and 10.

In another embodiment, the tunnel junction layer 16 is a combination of an AlGaAs layer and an InGaP layer, and the heavily-doped P-type layer 161 and the P-type filling layer 1610 are AlGaAs layers, and the N-type filling layer 1620 and the heavily-doped N-type layer 162 are InGaP layers (with a refractive index of 3.27). Please refer to Table 3 below.

TABLE 3

| | | | | | | Dopant | |
|---|---|---|---|---|---|---|---|
| | | | | Thick- | | Content | No. of |
| | Con- | | X | ness | Do- | (atoms/ | Stacked |
| Type | stituent | Material | value | (nm) | pant | cm³) | Pairs |
| Third | Second | AlₓGa₁₋ | 0.9 | 72 | Si | Greater | W |
| mirror | layer | ₓAs | | | | than | |
| layer | | | | | | 3.0 × 10¹⁸ | |
| (second | First | AlₓGa₁₋ | 0.12 | 60 | Si | Greater | — |
| N- | layer | ₓAs | | | | than | |
| DBR) | | | | | | 3.0 × 10¹⁸ | |
| Filling | N-type | InₓGa₁₋ | 0.5 | 57 | Si | Greater | |
| layer | filling | ₓP | | | | than | |
| | layer | | | | | 3.0 × 10¹⁸ | |
| Tunnel | Heavily- | InₓGa₁₋ | 0.5 | 15 | Te | Greater | |
| junction | doped | ₓP | | | | than | — |
| layer | N-type | | | | | 3.0 × 10²⁰ | |
| (TJ) | layer | | | | | | |
| | Heavily- | AlₓGa₁₋ | 0.9 | 15 | C | Greater | — |
| | doped | ₓAs | | | | than | |
| | P-type | | | | | 3.0 × 10²⁰ | |
| | layer | | | | | | |
| Filling | P-type | AlₓGa₁₋ | 0.9 | 45 | C | 3.0 × 10¹⁸ | — |
| layer | filling | ₓAs | | | | | |
| | layer | | | | | | |
| Second | Second | AlₓGa₁₋ | 0.9 | 72 | C | About | Z |
| mirror | layer | ₓAs | | | | 3.0 × 10¹⁸ | |
| layer | First | AlₓGa₁₋ | 0.12 | 60 | C | | |
| (P- | layer | ₓAs | | | | | |
| DBR) | | | | | | | |

In Table 3, which is similar to Table 2, the sum (60 nm) of the thickness of the heavily-doped P-type layer 161 (15 nm) and the thickness of the P-type filling layer 1610 (45 nm) is equal to the thickness of the first layer 301 (60 nm), and the sum (72 nm) of the thickness of the heavily-doped N-type layer 162 (15 nm) and the thickness of the N-type filling layer 1620 (57 nm) is equal to the thickness of the second layer 302 (72 nm). Wherein, W+Z=35, and Z is an integer between 1 and 10.

In another embodiment, the tunnel junction layer 16 is a combination of an AlGaAs layer and an InGaP layer, and the heavily-doped P-type layer 161 and the P-type filling layer 1610 are InGaP layers, and the N-type filling layer 1620 and the heavily-doped N-type layer 162 are AlGaAs layers. Please refer to Table 4 below.

TABLE 4

| | | | | | | Dopant | |
|---|---|---|---|---|---|---|---|
| | | | | Thick- | | Content | No. of |
| | Con- | | X | ness | Do- | (atoms/ | Stacked |
| Type | stituent | Material | value | (nm) | pant | cm³) | Pairs |
| Third | Second | AlₓGa₁₋ | 0.9 | 72 | Si | Greater | W |
| mirror | layer | ₓAs | | | | than | |
| layer | | | | | | 3.0 × 10¹⁸ | |
| (second | First | AlₓGa₁₋ | 0.12 | 60 | Si | Greater | |
| N- | layer | ₓAs | | | | than | |
| DBR) | | | | | | 3.0 × 10¹⁸ | |
| Filling | N-type | AlₓGa₁₋ | 0.9 | 57 | Si | Greater | — |
| layer | filling | ₓAs | | | | than | |
| | layer | | | | | 3.0 × 10¹⁸ | |
| Tunnel | Heavily- | AlₓGa₁₋ | 0.9 | 15 | Te | Greater | — |
| junction | doped | ₓAs | | | | than | |
| layer | N-type | | | | | 3.0 × 10²⁰ | |
| (TJ) | layer | | | | | | |
| | Heavily- | InₓGa₁₋ | 0.5 | 15 | C | Greater | — |
| | doped | ₓP | | | | than | |
| | P-type | | | | | 3.0 × 10²⁰ | |
| | layer | | | | | | |
| Filling | P-type | InₓGa₁₋ | 0.5 | 45 | C | 3.0 × 10¹⁸ | — |
| layer | filling | ₓP | | | | | |
| | layer | | | | | | |
| Second | Second | AlₓGa₁₋ | 0.9 | 72 | C | About | Z |
| mirror | layer | ₓAs | | | | 3.0 × 10¹⁸ | |
| layer | First | AlₓGa₁₋ | 0.12 | 60 | C | | |
| (P- | layer | ₓAs | | | | | |
| DBR) | | | | | | | |

In Table 4, which is similar to Table 2, the sum (60 nm) of the thickness of the heavily-doped P-type layer 161 (15 nm) and the thickness of the P-type filling layer 1610 (45 nm) is equal to the thickness of the first layer 301 (60 nm), and the sum (72 nm) of the thickness of the heavily-doped N-type layer 162 (15 nm) and the thickness of the N-type filling layer 1620 (57 nm) is equal to the thickness of the second layer 302 (72 nm). Wherein, W+Z=35, and Z is an integer between 1 and 10.

In another embodiment, the tunnel junction layer 16 is an AlGaAs layer. Unlike the previous embodiments, the sum of the thickness of the N-type filling layer 1620, the thickness of the heavily-doped N-type layer 162, the thickness of the heavily-doped P-type layer 161, and the thickness of the P-type filling layer 1610 is equal to the thickness of the second layer 302. Please refer to Table 5 below.

TABLE 5

| | | | | | | Dopant | |
|---|---|---|---|---|---|---|---|
| | | | | Thick- | | Content | No. of |
| | Con- | | X | ness | Do- | (atoms/ | Stacked |
| Type | stituent | Material | value | (nm) | pant | cm³) | Pairs |
| Third | Second | AlₓGa₁₋ | 0.9 | 72 | Si | Greater | W |
| mirror | layer | ₓAs | | | | than | |
| layer | | | | | | 3.0 × 10¹⁸ | |
| (second | First | AlₓGa₁₋ | 0.12 | 60 | Si | Greater | |
| N- | layer | ₓAs | | | | than | |
| DBR) | | | | | | 3.0 × 10¹⁸ | |
| Filling | N-type | AlₓGa₁₋ | 0.12 | 21 | Si | 3.0 × 10¹⁸ | — |
| layer | filling | ₓAs | | | | | |
| | layer | | | | | | |
| Tunnel | Heavily- | AlₓGa₁₋ | 0.12 | 15 | Te | Greater | — |
| junction | doped | ₓAs | | | | than | |
| layer | N-type | | | | | 3.0 × 10²⁰ | |
| (TJ) | layer | | | | | | |
| | Heavily- | | | | | | |
| | doped | AlₓGa₁₋ | 0.12 | 15 | C | Greater | — |
| | P-type | ₓAs | | | | than | |
| | layer | | | | | 3.0 × 10²⁰ | |
| Filling | P-type | AlₓGa₁₋ | 0.12 | 21 | C | 3.0 × 10¹⁸ | — |
| layer | filling | ₓAs | | | | | |
| | layer | | | | | | |
| Second | First | AlₓGa₁₋ | 0.12 | 60 | C | About | — |
| mirror | layer | ₓAs | | | | 3.0 × 10¹⁸ | |
| layer | Second | AlₓGa₁₋ | 0.9 | 72 | C | | Z |
| layer | xAs | ₓAs | | | | | |
| (P- | First | AlₓGa₁₋ | 0.12 | 60 | C | | |
| DBR) | layer | ₓAs | | | | | |

In Table 5, the sum (72 nm) of the thickness of the N-type filling layer 1620 (21 nm), the thickness of the heavily-doped N-type layer 162 (15 nm), the thickness of the heavily-doped P-type layer 161 (15 nm) and the thickness of the P-type filling layer 1610 (21 nm) is equal to the thickness of the second layer 302 (72 nm). Wherein, W+Z=35, and Z is an integer between 1 and 10.

In another embodiment, the tunnel junction layer 16 is an AlGaAs layer. Unlike the previous embodiments, the sum of the thickness of the N-type filling layer 1620, the thickness of the heavily-doped N-type layer 162, the thickness of the heavily-doped P-type layer 161, and the thickness of the P-type filling layer 1610 is the same as the thickness of the first layer 301. Please refer to Table 6 below.

TABLE 6

| | | | | | | Dopant | No. |
|---|---|---|---|---|---|---|---|
| | | | | Thick- | | Content | of |
| | Con- | | X | ness | Do- | (atoms/ | Stacked |
| Type | stituent | Material | value | (nm) | pant | cm³) | Pairs |
| Third | Second | AlₓGa₁₋ | 0.9 | 72 | Si | Greater | |
| mirror | layer | ₓAs | | | | than | W |
| layer | | | | | | 3.0 × 10¹⁸ | |
| (second | First | AlₓGa₁₋ | 0.12 | 60 | Si | Greater | |
| N- | layer | ₓAs | | | | than | |
| DBR) | | | | | | 3.0 × 10¹⁸ | |
| | Second | AlₓGa₁₋ | 0.9 | 72 | Si | About | — |
| | layer | ₓAs | | | | 3.0 × 10¹⁸ | |
| Filling | N-type | AlₓGa₁₋ | 0.12 | 15 | Si | 3.0 × 10¹⁸ | — |
| layer | filling | ₓAs | | | | | |
| | layer | | | | | | |
| Tunnel | Heavily- | AlₓGa₁₋ | 0.12 | 15 | Te | Greater | — |
| junction | doped | ₓAs | | | | than | |
| layer | N-type | | | | | 3.0 × 10²⁰ | |
| (TJ) | layer | | | | | | |
| | Heavily- | AlₓGa₁₋ | 0.12 | 15 | C | Greater | — |
| | doped | ₓAs | | | | than | |
| | P-type | | | | | 3.0 × 10²⁰ | |
| | layer | | | | | | |
| Filling | P-type | AlₓGa₁₋ | 0.12 | 15 | C | 3.0 × 10¹⁸ | — |
| layer | filling | ₓAs | | | | | |
| | layer | | | | | | |
| Second | Second | AlₓGa₁₋ | 0.9 | 72 | C | About | Z |
| mirror | layer | ₓAs | | | | 3.0 × 10¹⁸ | |
| layer | First | AlₓGa₁₋ | 0.12 | 60 | C | | |
| (P- | layer | ₓAs | | | | | |
| DBR) | | | | | | | |

In Table 6, the sum (60 nm) of the thickness of the N-type filling layer 1620 (15 nm), the thickness of the heavily-doped N-type layer 162 (15 nm), the thickness of the heavily-doped P-type layer 161 (15 nm) and the thickness of the P-type filling layer 1610 is equal to the thickness of the first layer 301. Wherein, W+Z=35, and Z is an integer between 1 and 10.

It is noteworthy that the configuration of the N-type filling layer 1620 and the P-type filling layer 1610 can make the sum of the thickness of the N-type filling layer 1620, the thickness of the tunnel junction layer 16, and the thickness of the P-type filling layer 1610 to be equal to the thickness of the first layer 301 or the thickness of the second layer 302 to comply with the thickness of each adjacent layer which is equal to a quarter of the emitting wavelength multiplied by the refractive index of each layer. Therefore, the configuration of the N-type filling layer 1620 and the P-type filling layer 1610 can reduce the thickness of the heavily-doped N-type layer 162 and the thickness of the heavily-doped P-type layer 161. For example, the thickness can be reduced to 15 nm, in order to further overcome the difficulty of controlling the reproducibility and uniformity of a traditional P-type semiconductor in a doping process with high carbon doping concentration due to the thickness of the first layer 301 or the thickness of the second layer 302.

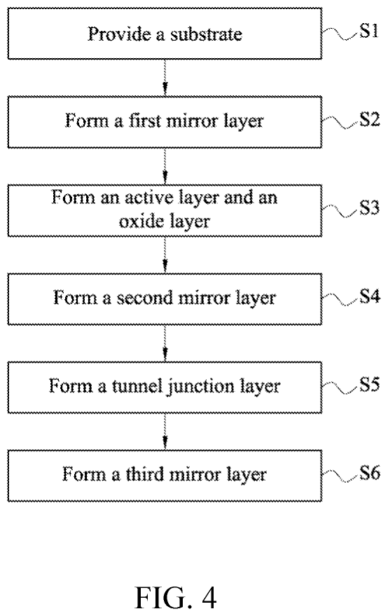

In FIG. 4, the VCSEL device 100 of the present disclosure is manufactured by a VCSEL device manufacturing method comprising the following epitaxy steps.

S1: Provide a substrate 11 in a cavity, wherein the substrate 11 is a GaAs substrate.

S2: Form a first mirror layer 12 (or first N-DBR) in-situ at the cavity on the substrate 11 by Molecular Beam Epitaxy (MBE) or Metal Organic Chemical Vapor Deposition (MOCVD), wherein the first mirror layer 12 is a doped silicon (Si) and/or tellurium (Te) AlGaAs layer.

S3: Sequentially form an active layer 13 and an oxide layer 14 in-situ at the cavity on the first mirror layer 12 by Molecular Beam Epitaxy (MBE) or Metal Organic Chemical Vapor Deposition (MOCVD), wherein the oxide layer 14 is manufactured in-situ or ex-situ or manufactured at different cavities by wet oxidation. Preferably, the oxide layer 14 is manufactured in-situ by wet oxidation, and the aluminium mole percentage of the oxide layer 14 is Al_{0.95}Ga_{0.05}As or above to facilitate the formation of an insulating oxide area 141 (or aluminium oxide area).

S4: Form a second mirror layer 15 (P-DBR) in-situ at the cavity on the oxide layer 14 by MBE or MOCVD.

S5: Form a tunnel junction layer 16 in-situ at the cavity on the second mirror layer 15 by MBE or MOCVD, wherein both the heavily-doped N-type layer 162 and the heavily-doped P-type layer 161 of the tunnel junction layer 16 have a thickness equal to 10 nm˜15 nm, and a doping concentration greater than 1.0×10²⁰ atoms/cm³.

S6: Form a third mirror layer 17 (second N-DBR) in-situ at the cavity on the tunnel junction layer 16 by MBE or MOCVD.

It is noteworthy that he epitaxy steps of the VCSEL device manufacturing method including the step S1 of providing a substrate, the step S2 of forming a first mirror layer, the step S3 of forming an active layer and an oxide layer, the step S4 of forming a second mirror layer, the step S5 of forming a tunnel junction layer, and the step S6 of forming a third mirror layer are performed in-situ in the same cavity and completed in a “first-time epitaxy” manner. Particularly the oxide layer 14 is also formed in-situ in the same cavity, and completed in the same “one-time epitaxy” manner as mentioned above. In this way, the tunnel junction layer 16 has dimensions (including area and shape) same as those of the second mirror layer 15 and/or the third mirror layer 17. In other words, if the tunnel junction layer 16 has an area smaller than the area of the second mirror layer 15 or the area of the third mirror layer 17, then it will be necessary to remove the tunnel junction layer 13 from the epitaxial cavity after its formation, and reduce the tunnel junction layer 16 in other cavities by dry or wet etching, and then transfer them back to the epitaxy cavity of a “second-time epitaxy” of the third mirror layer 17. Obviously, moving the tunnel junction layer into and out from the epitaxial cavity twice will cause a risk of process variation, so that the VCSEL device manufacturing method of the present disclosure performs an in-situ one-time epitaxy to avoid the risk of process variation.

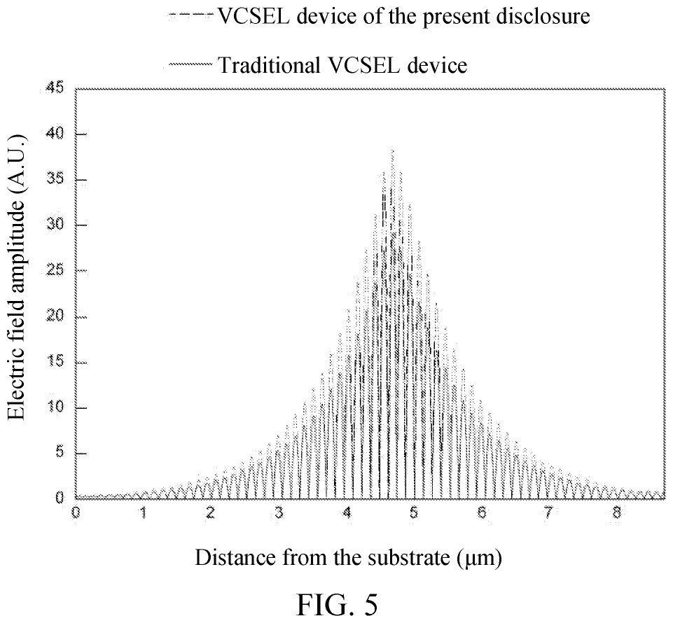

The structure of a traditional VCSEL device includes a first electrode, a substrate, an N-DBR, an active layer, an oxide layer, a P-DBR and a second electrode sequentially arranged from bottom to top. In an embodiment of the present disclosure, the first electrode, substrate, active layer, oxide layer and second electrode of the VCSEL device 100 have the same composition, structure and thickness of the traditional VCSEL device. The differences between the VCSEL device 100 of the present disclosure and the traditional VCSEL device different are: (1) The VCSEL device 100 of the present disclosure has the tunnel junction layer 16; (2) The first mirror layer 12 (first N-DBR) of the VCSEL device 100 of the present disclosure has 25 stacked pairs 30, and the corresponding N-DBR of the traditional VCSEL device has 35 stacked pairs; (3) the P-type distributed Bragg reflector structure 20 of the VCSEL device 100 of the present disclosure has the second mirror layer 15 (P-DBR) with 10 (Z=10) stacked pairs 30 and the third mirror layer 17 (second N-DBR) has 25 (W=25) stacked pairs 30, and the second mirror layer 15 and the third mirror layer 17 have a total of 35 stacked pair 30, and the corresponding P-DBR of the traditional VCSEL device has 25 stacked pairs. Obviously, the VCSEL device 100 of the present disclosure has the P-DBR 10 with only 10 stacked pairs, which is less than the P-DBR with 25 stacked pairs in the traditional VCSEL device, so that the VCSEL device 100 of the present disclosure can reduce the series resistance of the VCSEL device significantly. In FIG. 5, the series resistance is reduced, so that the VCSEL device 100 of the present disclosure improves the vertical distribution of electric field intensity by 32.3% over the traditional VCSEL device. The vertically distributed electric field intensity can be used with a commercially available VCSEL simulator (such as LASERMOD) to execute numerical analysis.

The present disclosure uses the tunnel junction layer to switch a part of the P-DBR of the VCSEL device to N-DBR in order to reduce the series resistance of the VCSEL device, and the tunnel junction layer is not used for the effect of a current-limiting aperture. In the present disclosure, the configuration of the N-type filling layer and the P-type filling layer can reduce the thickness of the heavily doped N-type layer and the thickness of the heavily doped P-type layer to comply with the design of reflectively of each stacked layer of the DBR. The VCSEL device manufacturing method of the present disclosure adopts an in-situ and one-time epitaxy to avoid the risk of process variation.

What is claimed is:

1. A vertical cavity surface emitting laser (VCSEL) device, comprising:
a substrate;
a first mirror layer, disposed at top of the substrate, wherein the first mirror layer is a first N-type distributed Bragg reflector;
an active layer, disposed at top of the first mirror layer;
an oxide layer, disposed at top of the active layer;
a second mirror layer, disposed at top of the oxide layer, wherein the second mirror layer is a P-type distributed Bragg reflector;
a tunnel junction layer, disposed at top of the second mirror layer; and
a third mirror layer, disposed at top of the tunnel junction layer, wherein the third mirror layer is a second N-type distributed Bragg reflector, and the second mirror layer and the third mirror layer comprise a plurality of stacked pairs respectively, and each of the stacked pairs comprises a first layer and a second layer; the tunnel junction layer comprises a heavily-doped N-type layer and a heavily-doped P-type layer, and an N-type filling layer is disposed between the heavily-doped N-type layer and the third mirror layer, and a P-type filling layer is disposed between the heavily-doped P-type layer and the second mirror layer, and a sum of a thickness of the heavily-doped N-type layer and a thickness of the N-type filling layer is equal to a thickness of the second layer, and a sum of a thickness of the heavily-doped P-type layer and a thickness of the P-type filling layer is equal to a thickness of the first layer; or the sum of the thickness of the heavily-doped N-type layer, the thickness of the N-type filling layer, the thickness of the heavily-doped P-type layer and the thickness of the P-type filling layer is equal to the thickness of the first layer or the thickness of the second layer.

2. The VCSEL device according to claim 1, wherein the tunnel junction layer has an area equal to the area the second mirror layer and/or the area of the third mirror layer.

3. The VCSEL device according to claim 1, wherein the oxide layer comprises an oxide aperture disposed at a central area thereof and an oxide area disposed around the oxide aperture, and the oxide aperture has an area smaller than the area of the tunnel junction layer.

4. The VCSEL device according to claim 1, wherein the tunnel junction layer has an area equal to the area of the second mirror layer and/or the area of the third mirror layer; and the oxide layer comprises an oxide aperture disposed at a central area thereof, and an oxide area disposed around the oxide aperture, and the oxide aperture has an area smaller than the area of the tunnel junction layer.

5. A VCSEL device manufacturing method, comprising epitaxy steps of:
providing a substrate in a cavity;
forming a first mirror layer in-situ at the cavity on the substrate, wherein the first mirror layer is a first N-type distributed Bragg reflector;
forming an active layer and an oxide layer sequentially in-situ at the cavity on the first mirror layer;
forming a second mirror layer in-situ at the cavity on the oxide layer, wherein the second mirror layer is a P-type distributed Bragg reflector;
forming a tunnel junction layer in-situ at the cavity on the second mirror layer; and
forming a third mirror layer in-situ at the cavity on the tunnel junction layer, wherein the third mirror layer is a second N-type distributed Bragg reflector, and the tunnel junction layer has an area equal to the area of the second mirror layer and/or the area of the third mirror layer; the oxide layer comprises an oxide aperture disposed at a central area thereof and an oxide area disposed around the oxide aperture, and the oxide aperture has an area smaller than the area of the tunnel junction layer; the second mirror layer and the third mirror layer comprises a plurality of stacked pairs respectively, and each of the stacked pairs comprises a first layer and a second layer; the tunnel junction layer comprises a heavily-doped N-type layer and a heavily-doped P-type layer, and an N-type filling layer is disposed between the heavily-doped N-type layer and the third mirror layer, and a P-type filling layer is disposed between the heavily-doped P-type layer and the second mirror layer, and a sum of a thickness of the heavily-doped N-type layer and a thickness of the N-type filling layer is equal to a thickness of the second layer, and a sum of a thickness of the heavily-doped P-type layer and a thickness of the P-type filling layer is equal to a thickness of the first layer; or the sum of the thickness of the heavily-doped N-type layer, the thickness of the N-type filling layer, the thickness of the heavily-doped P-type layer and the thickness of the P-type filling layer is equal to the thickness of the first layer or the thickness of the second layer.
